(19) United States
(12) Patent Application Publication
(10) Pub. No.: US 2014/0197068 A1
(43) Pub. Date: Jul. 17, 2014

(54) WAFER HOLDING APPARATUS

(71) Applicant: Samsung Electronics Co., Ltd., Suwon-Si (KR)

(72) Inventors: Hyun-Ho CHO, Suwon-si (KR); Hyeog-Ki KIM, Hwaseong-si (KR); Kwang-Shin LIM, Yongin-si (KR)

(73) Assignee: SAMSUNG ELECTRONICS CO., LTD., Suwon-Si (KR)

(21) Appl. No.: 14/138,281

(22) Filed: Dec. 23, 2013

(30) Foreign Application Priority Data
Jan. 16, 2013 (KR) 10-2013-0004687

(51) Int. Cl. H01L 21/673

(52) U.S. Cl. CPC H01L 21/67383
USPC 206/711

(57) ABSTRACT

A wafer holding apparatus including a container body having a space to receive a wafer and a front opening, a door disposed at the front opening, and a first supporting part disposed on an inner wall of the door may be provided. For example, the first supporting part may include a frame coupled to the inner wall of the door, a plurality of elastic ribs protruding from the frame, a support structure coupled to the plurality of elastic ribs and defining a plurality of grooves, which is spaced apart from the door by the elastic ribs and configured to receive a peripheral portion of the wafer.

### CROSS-REFERENCE TO RELATED APPLICATION

This application claims priority under 35 USC §119 to Korean Patent Application No. 10-2013-0004687, filed on Jan. 16, 2013 in the Korean Intellectual Property Office (KIPO), the contents of which are herein incorporated by reference in their entirety.

### BACKGROUND

1. Field

Example embodiments relate to wafer holding apparatuses. More particularly, example embodiments relate wafer holding apparatuses for manufacturing a semiconductor device.

2. Description of the Related Art

Wafers used to manufacture semiconductor devices are received in a Front Opening Unified Pod (FOUP) for transportation. FOUP is a wafer holding apparatus being standardized. Wafers may be damaged from impact in the FOUP while the wafer is being transported.

Traditional wafer holding apparatuses may not effectively protect and support the wafer from impact.

### SUMMARY

Example embodiments provide wafer holding apparatuses capable of effectively supporting and protecting a wafer.

According to example embodiments, a wafer holding apparatus may include a container body having a space and an front, the space configured to receive a wafer, a door disposed on the front opening, and a first supporting part disposed on an inner wall of the door. The first supporting part may include a frame mounted on the inner wall of the door, a plurality of elastic ribs protruding from the frame and a support structure coupled to the plurality of elastic ribs and defining a plurality of grooves, the plurality of grooves spaced apart from the door by the elastic ribs and configured to receive a peripheral portion of the wafer.

In example embodiments, the first supporting part may include a plurality of wafer contacting portion. Each of the wafer contacting portions may include a first inclined surface and a second inclined surface that form each of the grooves.

In example embodiments, the wafer contacting portions may be arranged in a direction substantially perpendicular to the wafer. Adjacent wafer contacting portions adjacent may be configured to be coupled to each other.

In example embodiments, the container body may include a top portion, a bottom portion opposite to the top portion, a side portion and a rear portion. The side portion and the rear portion may connect the top portion to the bottom portion. Second supporting parts may be formed on an inner surface of the side portion. The first and second supporting parts may be configured to support the wafer.

In example embodiments, the second supporting part may include a plurality of slits, which are configured to receive the wafer in an inserted manner.

In example embodiments, each of the second supporting parts may be disposed on the inner surface of the side portion and on an inner surface of the rear portion. The second supporting part may have a shape substantially same as that of the first supporting part.

In example embodiments, second supporting part holders on the inner surface of the side portion and the inner surface of the rear portion are configured to hold the second supporting parts. The second supporting parts may be configured to be removable from the second supporting part holders.

In example embodiments, thickness of the elastic ribs of the first supporting part may be smaller than that of the frame.

In example embodiments, a peak may be at a junction at which the second inclined surface and a first inclined surface of an adjacent wafer contacting portion meet. A protrusion may be protrudes from the peak in a direction substantially parallel with the wafer.

In example embodiments, an angle defined by the first inclined surface and the second inclined surface may be about 140 degrees to about 160 degrees.

In example embodiments, the wafer contacting portions of the first supporting part may include a plurality of first contacting portions and a plurality of second contacting portions spaced apart from the first contacting portions. Each of the first and second contacting portions may include the first inclined surface and the second inclined surface. The first inclined surface and the second inclined surface may define the grooves that is to contact the wafer. The elastic ribs may include first elastic ribs. The first elastic ribs may connect the first wafer contacting portions to the frame and the second elastic ribs may connect the second wafer contacting portions to the frame.

In example embodiments, the first wafer contacting portions may be arranged in a direction substantially perpendicular to the wafer. The first and second inclined surfaces in each of the first wafer contacting portions may be arranged continuously and alternately The second wafer contacting portions may be arranged in the direction substantially perpendicular to the wafer. the first and second inclined surfaces in each of the second wafer contacting portions may be arranged continuously and alternately

In example embodiments, an angle defined by the first inclined surface and the second inclined surface may be about 140 degrees to about 160 degrees.

In example embodiments, a first supporting part holder may be disposed on the inner wall of the door. The frame of the first supporting part may be coupled to the first supporting part holder.

In example embodiments, the first supporting part may include thermo-hardening resin.

According to example embodiments, a wafer holding apparatus include a first supporting part including a first inclined surface and a second inclined surface, so that a wafer may be firmly held in the wafer holding apparatus.

In example embodiments, the first supporting part may include elastic material and elastic ribs so that the wafer may be firmly held due to elastic deformation of the elastic ribs when the wafer is received into the wafer holding apparatus.

In example embodiments, the first inclined surface and the second inclined surface may form an angle so that the wafer may be firmly held in the wafer holding apparatus.

In example embodiments, a first supporting part holder may be disposed on an inner wall of a door so that the first supporting part may be easily attached to and/or detached from the door. Thus, the first supporting part may be replaced when worn out.

The first wafer contacting portions and the second wafer contacting portions may be disposed side-by-side.

According to example embodiments, a wafer holding apparatus includes a container having an open side configured to receive a wafer therethrough, a door configured to close the open side, and a first supporting part coupled to the door, a first supporting part coupled to the door and including at least one groove configured to hold a peripheral portion of the wafer.

The supporting part may include a corrugated support structure defining the at least one groove.

The supporting part may be spaced apart from the door by a plurality of elastic ribs connected to the corrugated support structure.

The door may include a holder configured to couple the supporting part with the door.

The wafer holding apparatus may further includes a plurality of protrusions at a plurality of peaks of the corrugated support structure, the protrusions extending in a direction substantially parallel with the wafer.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is an exploded perspective view illustrating a wafer holding apparatus in accordance with some example embodiments;

FIG. 2 is a perspective view illustrating a first supporting part of the wafer holding apparatus of FIG. 1;

FIG. 3 is an enlarged cross-sectional view of a portion where the first supporting part and a wafer of FIG. 1 contact each other to illustrate that the wafer is supported by the first supporting part;

FIG. 4 is a perspective view illustrating a first supporting part in accordance with other example embodiments;

FIG. 5 is an enlarged cross-sectional view of a portion at which the first supporting part and a wafer of FIG. 4 contact each other;

FIG. 6 is a perspective view illustrating a first supporting part in accordance with still other example embodiments;

FIG. 7 is a perspective view illustrating a first supporting part in accordance with yet other example embodiments;

FIG. 8 is an exploded perspective view illustrating a wafer holding apparatus in accordance with further other example embodiments;

FIG. 9 is a plan cross-sectional view of the wafer holding apparatus of FIG. 1 with a wafer received;

FIG. 10 is a plan cross-sectional view of the wafer holding apparatus of FIG. 8 with a wafer received;

FIG. 11 is an enlarged cross-sectional view of a portion at which the first supporting part and a wafer of FIG. 9 or FIG. 10 contact each other;

FIG. 12 is a plan cross-sectional view of the wafer holding apparatus of FIG. 6 with a wafer received; and

FIG. 13 is an enlarged cross-sectional view of a portion at which the first supporting part and a wafer of FIG. 12 contact each other.

### DETAILED DESCRIPTION OF EXAMPLE EMBODIMENTS

Example embodiments will now be described more fully with reference to the accompanying drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements throughout, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

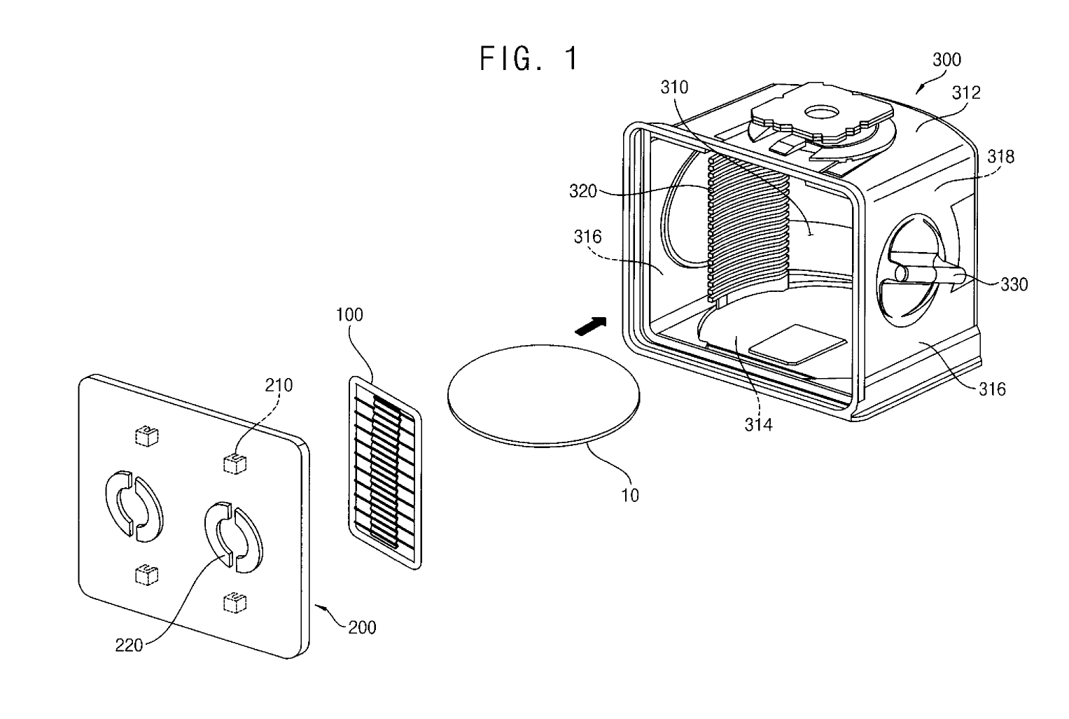

FIG. 1 is an exploded perspective view illustrating a wafer holding apparatus in accordance with example embodiments.

Referring to FIG. 1, the wafer holding apparatus may include a first supporting part 100, a door 200 and a container body 300.

The container body 300 may include a top portion 312, a bottom portion 314, a side portion 316 and a rear portion 318. The top portion 312 and the bottom portion 314 may face each other. The side portion 316 and the rear portion 318 may connect the top portion 312 to the bottom portion 314. The portion 312, the bottom portion 314, the side portion 316 and the rear portion 318 may form a receiving space to receive a wafer 10. The container body 300 may define an opening portion 310. The wafer 10 may be inserted in and exported out through the opening portion 310.

A handle 330 may be formed on the side portion 316. Using the handle 330, a user may manually carry the wafer holding apparatus.

A second supporting part 320 may be disposed in the side portion 316. The second supporting part 320 may have a plurality of slits. Each of the slit may support the wafer 10. Although only one wafer 10 is described in the figures, a plurality of wafers may be supported by a plurality of the slits, respectively. Thus, a plurality of the wafers 10 may be inserted by sliding-type and supported by the second supporting part 320.

The wafer 10 may be a 300 mm wafer in a thin disc form for manufacturing a semiconductor device.

The door 200 may be disposed at the opening 310 of the container body 300 when the wafer is received in the container body 300. The door 200 may protect the wafer 10 from being contaminated by a foreign matter. The door 200 may have a first supporting part holder 210 disposed on an inner wall of the door 200 and an open-and-shut controller 220 disposed outside of the door 200.

The first supporting part 100 may be disposed on the inner wall of the door 200. The first supporting part 100 may be attached to the door 200 by the first supporting part holder 210. The first supporting part 100 may support and make contact with the wafer 10 to mitigate or prevent the wafer 10 from escaping a receiving position in the container body 300. The first supporting part 100 may be separable from the first supporting part holder 210 for replacement.

The first supporting part 100 may include elastic material. For example, the first supporting part 100 may include thermo-hardening resin, e.g., poly-ether-ether-ketone (PEEK), poly-butylene-terephthalate (PBT), and etc. Further, a surface of the first supporting part 100 may be smoothly polished to reduce friction between the wafer 10 and the first supporting part 100 when the first supporting part 100 makes contact with the wafer 10. For example, roughness of the surface of the first supporting part 100 may be smaller than 0.1 μm.

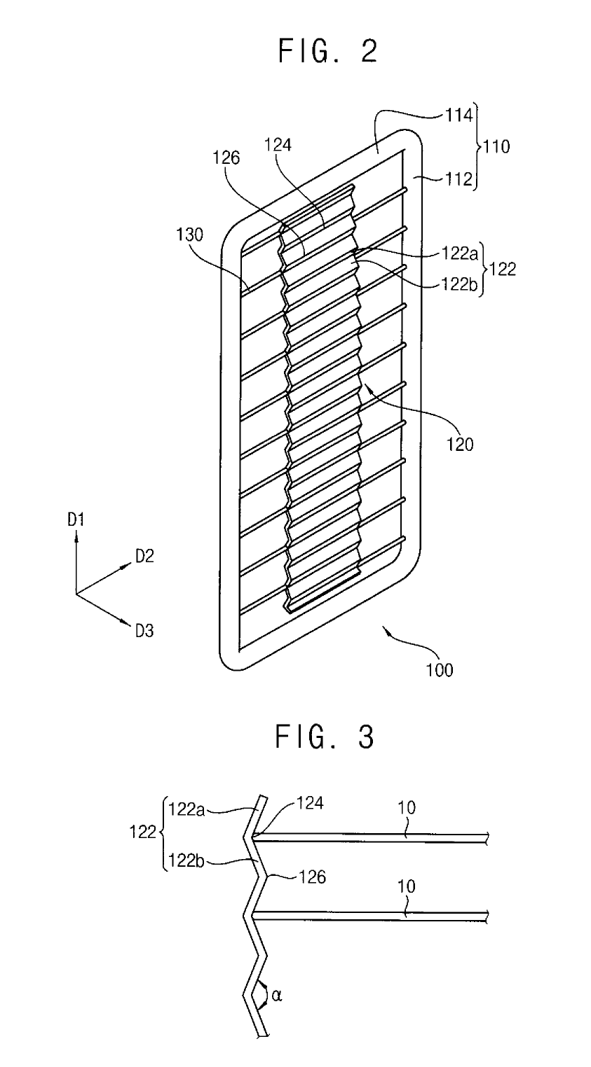

FIG. 2 is a perspective view illustrating a first supporting part of the wafer holding apparatus of FIG. 1.

Referring to FIG. 2, the first supporting part 100 may include a frame 110, a contacting part 120 including a wafer contacting portion 122, and an elastic ribs 130. The first supporting part 100 may contact and support the wafer 10.

The frame 110 may include a first frame 112 and a second frame 114. The first frame may extend in a first direction D1. Two of first frames may be disposed by spaced apart from each other in a second direction D2 which is substantially perpendicular to the first direction D1. The second frame 114 may extend in the second direction D2. Two of second frames may be disposed by spaced apart from each other in the first direction D1. The first frames 112 and the second frame 114 may be connected each other so that the frame 110 having a quadrangle shape is formed. A portion of the frame 110 may be coupled to the first supporting part holder 210 of the door 200 so that the first supporting part 100 may be attached to the door.

The contacting part 120 may be disposed in a space formed by the frame 110, which has the quadrangle shape. The contacting part 120 may include a plurality of the wafer contacting portion 122 arranged in the second direction D2. The wafer contacting portion 122 may include a first inclined surface 122a and a second inclined surface 122b. The first inclined surface 122a and the second inclined surface 122b may be continuously and alternatingly arranged so that a plurality of peak 126 and a plurality of groove 124 are formed. The wafer 10 may contact and may be received in the groove 124, which may be formed by the first inclined surface 122a and the second inclined surface 122b.

The elastic ribs 130 may connect the frame 110 to the contacting part 120. The elastic ribs 130 may protrude from the frame 110 in parallel with the first direction D1 and may be connected to the contacting part 120. The elastic ribs 130 may include the elastic material so that the contacting part 120 may be slightly moved in a third direction D3 substantially perpendicular to the first and second directions D1 and D2. Thus, although the wafer presses the contacting part 120, the wafer may be stably held and/or supported in the contacting part 120 due to elasticity of the elastic ribs 130.

FIG. 3 is an enlarged cross-sectional view of a portion where the first supporting part and a wafer of FIG. 1 contact each other to illustrate that the wafer is supported by the first supporting part.

Referring to FIGS. 3 and 2, a peripheral portion of the wafer 10 may be held in and/or contact the groove 124, which is formed by the first inclined surface 122a and the second inclined surface 122b.

The groove 124 having a first angle a may be formed by the first inclined surface 122a and the second inclined surface 122b. Generally, patterns of the wafer may be formed far from a boundary of the wafer by several millimeters. When the first angle α is smaller than 120 degree, patterns formed adjacent to the boundary of the wafer may be damaged by contacting with the first inclined surface 122a or the second inclined surface 122b. Further, when the first angle a is larger than 120 degree, the wafer 10 may not be firmly held. Thus, the first angle a may preferably be about 140 to 160 degree.

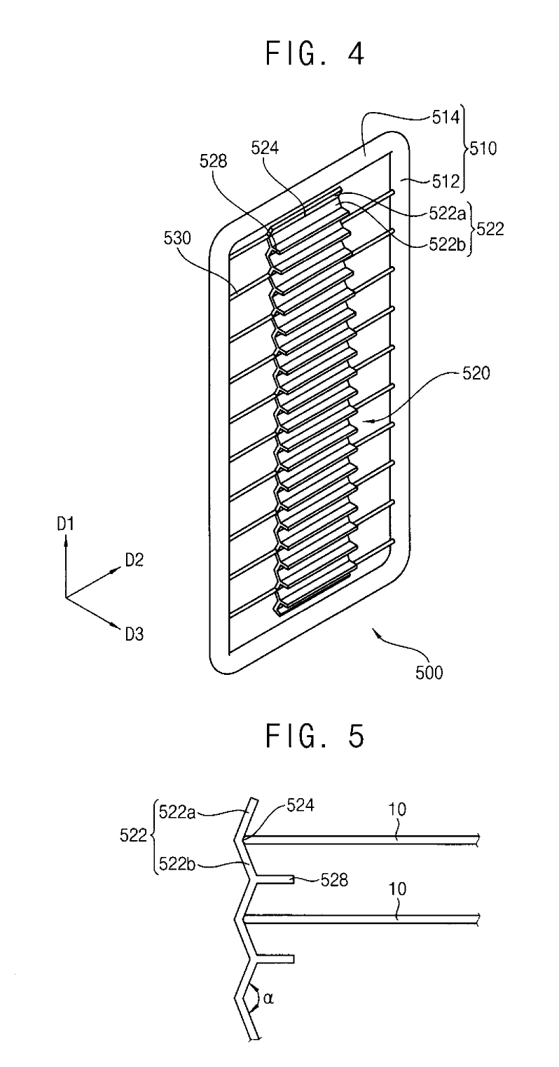

FIG. 4 is a perspective view illustrating a first supporting part in accordance with other example embodiments.

Referring to FIG. 4, the first supporting part 500 may be substantially same as a first supporting part 100 of FIG. 2, except for a protrusion 528 of a contacting part 520. Thus, any further detailed descriptions concerning the same elements will be omitted.

The first supporting part 500 may include a frame 510, a contacting part 520 including a wafer contacting portion 522, and an elastic ribs 530. The frame 510 may include a first frame 512 and a second frame 514.

The contacting part 520 may be disposed in a space formed by the frame 510 having the quadrangle shape. The contacting part 520 may include a plurality of the wafer contacting portion 522 arranged in a second direction D2. The wafer contacting portion 522 may include a first inclined surface 522a and a second inclined surface 522b. The first inclined surface 522a and the second inclined surface 522b may be continuously and alternatingly arranged so that a plurality of peak 526 and a plurality of groove 524 are formed. The protrusion 528 may extend from the peak 526 in a third direction D3.

FIG. 5 is an enlarged cross-sectional view of a portion at which the first supporting part and a wafer of FIG. 4 contact each other.

Referring to FIGS. 4 and 5, a peripheral portion of the wafer 10 may be held in and/or contact the groove 524, which is formed by the first inclined surface 522a and the second inclined surface 522b.

The groove 524 having a first angle a may be formed by the first inclined surface 522a and the second inclined surface 522b. The first angle α may be, for example, about 140 to 160 degree.

The protrusion 528 may reduce or prevent the wafer 10 from separating and drifting. The protrusion 528 may be disposed between the wafers 10 adjacent each other, and may extend in a direction substantially in parallel with the wafer 10 so that the protrusion 528 effectively mitigate or prevent the wafer 10 from being damaged.

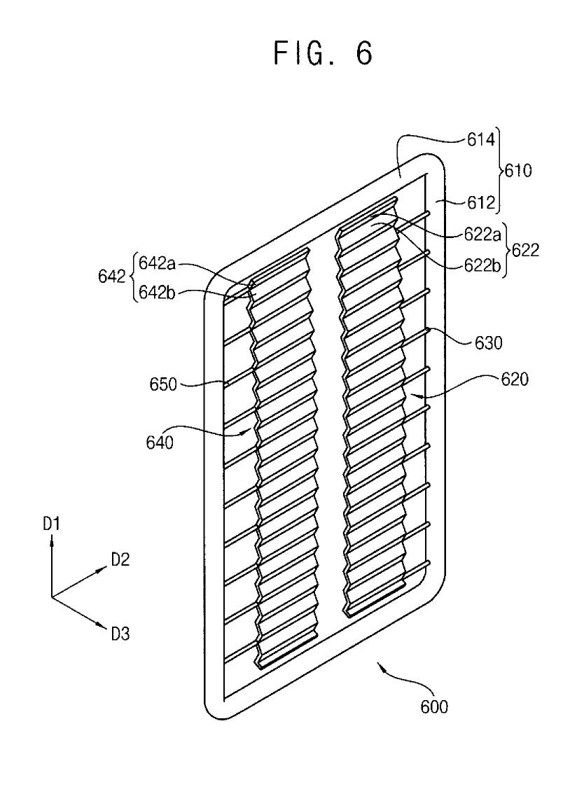

FIG. 6 is a perspective view illustrating a first supporting part in accordance with still other example embodiments.

Referring to FIG. 6, the first supporting part 600 may be substantially same as a first supporting part 100 of FIG. 2, except for a first contacting part 620, a first elastic ribs 630, a second contacting part 640 and a second elastic ribs 650. Thus, any further detailed descriptions concerning the same elements will be omitted.

The first supporting part 600 may include a frame 610, a first contacting part 620, a first elastic ribs 630, a second contacting part 640 and a second elastic ribs 650. The frame 610 may include a first frame 612 and a second frame 614.

The first contacting part 620 may be disposed in a space formed by the frame 610, which has the quadrangle shape. The first contacting part 620 may include a plurality of first wafer contacting portion 622 arranged in a second direction D2. The first wafer contacting portion 622 may include a first inclined surface 622a and a second inclined surface 622b. The first inclined surface 622a and the second inclined surface 622b may be continuously and alternatingly arranged so that a plurality of peak and a plurality of groove are formed.

The first contacting part 620 may be connected to the first elastic ribs 630, which extends from the first frame 612 in the second direction D2.

The second contacting part 640 may be disposed in a space formed by the frame 610, which has the quadrangle shape. The second contacting part 640 may be disposed adjacent to the first contacting part 620. The second contacting part 640 may include a plurality of the second wafer contacting portion 642 arranged in the second direction D2. The second wafer contacting portion 642 may include a first inclined surface 642a and a second inclined surface 642b. The first inclined surface 622a and the second inclined surface 622b may be continuously and alternatingly arranged so that a plurality of peak and a plurality of groove are formed. The second contacting part 640 may be connected to the frame 610 through the second elastic ribs 640. The second contacting part 640 and the second elastic ribs 650 may be symmetrical to the first contacting part 620 and the first elastic ribs 630 with respect to a central line of the first supporting part 600 which is in parallel with the first direction D1.

The peripheral portion of the wafer 10 may be held in and/or contact the grooves, which are formed by the first and second inclined surfaces 622a or 642a and 622b or 642b of the first and second wafer contacting portions 622 and 642. Thus, the wafer 10 may contact the first and second wafer contacting portions 622 and 642 so that the wafer 10 is held in the wafer holding apparatus.

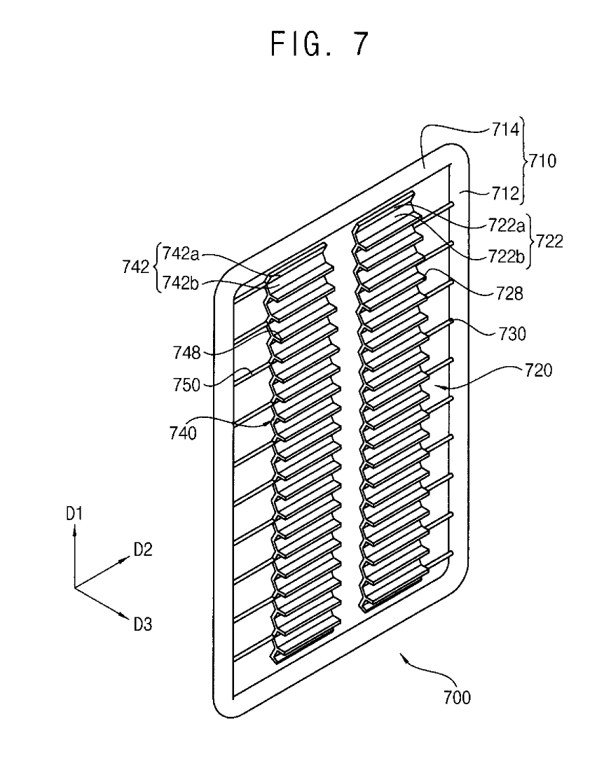

FIG. 7 is a perspective view illustrating a first supporting part in accordance with yet other example embodiments.

Referring to FIG. 7, the first supporting part 700 may be substantially same as a first supporting part 600 of FIG. 6, except for a first protrusion 728 of a first contacting part 720 and a second protrusion 748 of a second contacting part 740. Thus, any further detailed descriptions concerning the same elements will be omitted.

The first supporting part 700 may include a frame 710, a first contacting part 720, a first elastic ribs 730, a second contacting part 740 and a second elastic ribs 750. The frame 710 may include a first frame 712 and a second frame 714.

The first contacting part 720 may include a first wafer contacting portion 722 formed by a first inclined surface 722a and a second inclined surface 722b. The first inclined surface 722a and the second inclined surface 722b may be continuously and alternatingly arranged so that a plurality of peak and a plurality of groove are formed. The first protrusion 728 may extend from the peak in a third direction D3.

The second contacting part 740 may include a first wafer contacting portion 742 formed by a first inclined surface 742a and a second inclined surface 742b, and a second protrusion 748. The second contacting part 740 may be connected to the frame 710 through the second elastic ribs 750. The second contacting part 740 and the second elastic ribs 750 may be symmetrical to the first contacting part 720 and the first elastic ribs 730 with respect to a central line of the first supporting part 700 which is in parallel with a first direction D1.

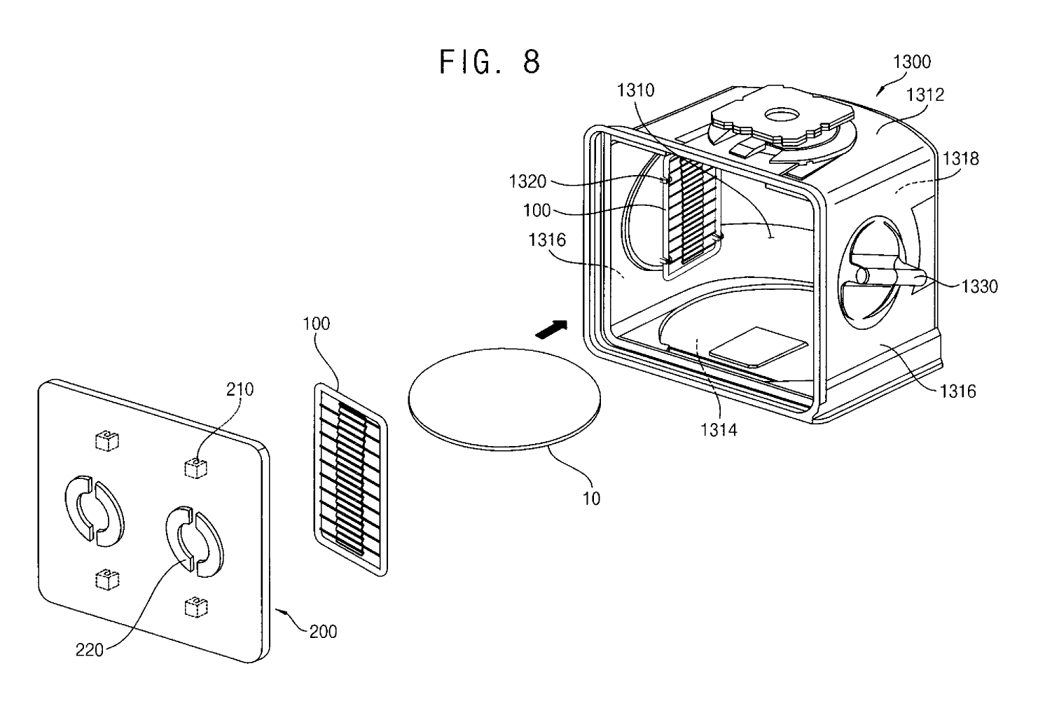

FIG. 8 is an exploded perspective view illustrating a wafer holding apparatus in accordance with further other example embodiments.

Referring to FIG. 8, the wafer holding apparatus may be substantially same as a wafer holding apparatus of FIG. 1, expect that a plurality of first supporting part 100 may be disposed in the wafer holding apparatus instead of the second supporting part 320 of FIG. 1). Thus, any further detailed descriptions concerning the same elements will be omitted.

The wafer holding apparatus may include a plurality of first supporting part 100, a door 200 and a container body 1300.

The container body 1300 may include a top portion 1312, a bottom portion 1314, a side portion 1316 and a rear portion 1318. The container body 1300 may define an opening portion 1310. The wafer 10 may be inserted in and exported out through the opening portion 1310. A handle 1330 may be formed on the side portion 1316.

Further, the first supporting part 100 may be disposed in the side portion 1316. The first supporting part 100 may be coupled to and/or separated from the container body 1300 by a first supporting part holder 1320 formed on an inner surface of the side portion 1316.

The door 200 may have the first supporting part holder 210 disposed on an inner surface of the door 200 and the open-and-shut controller 220 disposed outside of the door 200.

The first supporting part 100 may be disposed on the inner surface of the door 200. The first supporting part 100 may be attached to the door 200 by the first supporting part holder 210.

The first supporting part 100 may be disposed on an inner surface of the rear portion 1318 of the container body 1300. Thus, a plurality of the first supporting parts 100 may contact the wafer 10 so that the wafer 10 is held in the wafer holding apparatus.

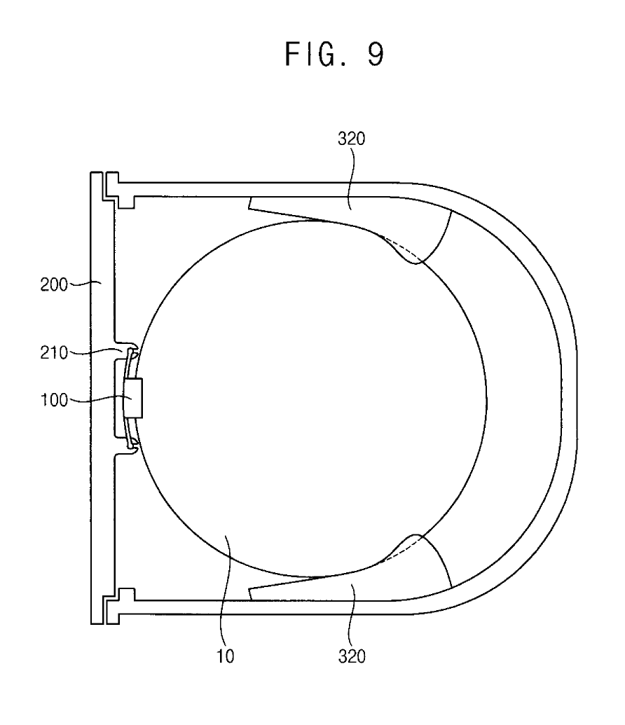

FIG. 9 is a plan cross-sectional view of the wafer holding apparatus of FIG. 1 with a wafer received.

Referring to FIGS. 9 and 1, the wafer 10 may be inserted in a slit of the second supporting part 320. After that, the door 200 may be closed so that the first supporting part 100 coupled to the first supporting part holder 210 contacts the wafer 10. Thus, the wafer 10 may be held in the wafer holding apparatus.

The first supporting part 100 may include elastic material. The first supporting part 100 may be elastically deformed by contacting with the wafer 10 so that the first supporting part 100 may firmly hold the wafer 10.

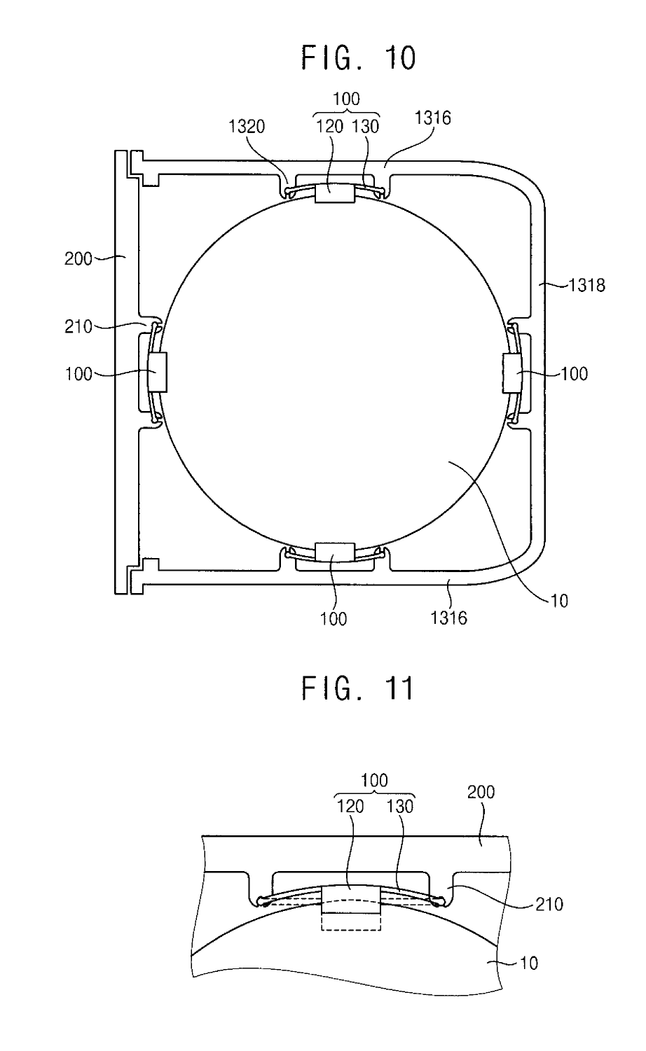

FIG. 10 is a plan cross-sectional view of the wafer holding apparatus of FIG. 8 with a wafer received.

Referring to FIGS. 8 and 10, the wafer 10 may be inserted in the wafer contacting portions 122 of the first supporting parts 100, which are coupled to the first supporting part holder 1320 in the container body 1300. After that, the door 200 may be closed so that the first supporting parts 100 on an inner wall of the door 200 may contact with the wafer 10. Thus, the wafer 10 may be held in the wafer holding apparatus.

The first supporting part 100 may include elastic material. The first supporting part 100 may be elastically deformed by contacting with the wafer 10, so that the first supporting part 100 may firmly hold the wafer 10.

FIG. 11 is an enlarged cross-sectional view of a portion at which the first supporting part and a wafer of FIG. 9 or FIG. 10 contact each other.

Referring to FIGS. 11, 9 and 10, when the wafer 10 is received in the wafer holding apparatus, the first supporting part 100 may be elastically deformed by contacting with the wafer 10 so that the first supporting part 100 may firmly hold the wafer 10. The first supporting part 100 may include elastic material. When the wafer 10 is received, the first supporting part 100 may be elastically deformed from an original position (dotted line in figure) to a position being opposite to the wafer 10. For example, the elastic ribs 130 may have a thickness smaller than that of the frame 100 or a contacting part 120 so that the elastic ribs 130 is easily elastically deformed. When the wafer 10 is exported, the first supporting part 100 may return to the original position.

Although a plurality of the wafers 10 are received, the wafer contacting portions 122 may be connected to the elastic ribs 130 respectively so that the wafers 10 may be firmly held or supported.

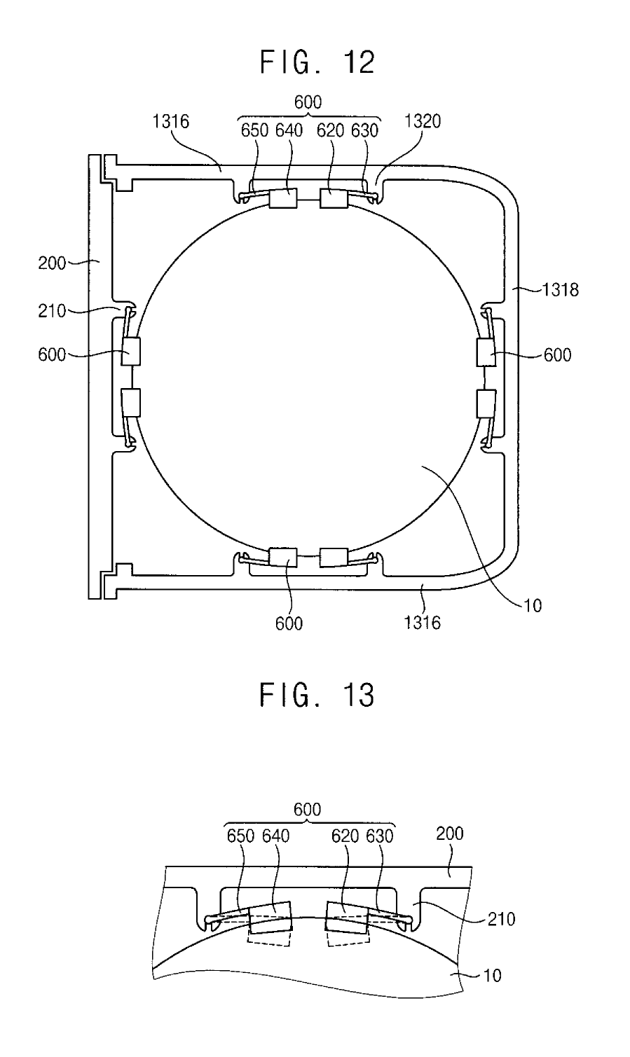

FIG. 12 is a plan cross-sectional view of the wafer holding apparatus of FIG. 6 with a wafer received.

Referring to FIG. 12, the wafer 10 is inserted in first and second wafer contacting portions (refers to 622 and 624 of FIG. 6) of the first supporting parts 600 which are coupled to the first supporting part holder 1320 in the container body 1300. After that, the door 200 is closed, so that the first supporting part 600 on an inner wall of the door 200 makes contact with the wafer 10. Thus, the wafer 10 may be held in the wafer holding apparatus.

The first supporting part 600 includes elastic material. The first supporting part 600 is elastically deformed by contacting with the wafer 10, so that the first supporting part 600 may firmly fix the wafer 10.

FIG. 13 is an enlarged cross-sectional view of a portion at which the first supporting part and a wafer of FIG. 12 contact each other.

Referring to FIGS. 13, 12 and 6, when the wafer 10 is received in the wafer holding apparatus, the first supporting part 600 may be elastically deformed by contacting with the wafer 10 so that the first supporting part 600 firmly hold the wafer 10. The first supporting part 600 may include elastic material. When the wafer 10 is received, the first supporting part 600 may be elastically deformed from an original position (dotted line in figure) to a position being opposite to the wafer 10. For example, the first and second elastic ribs 630 and 650 may have thicknesses smaller than that of a frame 610 or those of the first and second contacting parts 620 and 640 so that the elastic ribs 130 are easily elastically deformed. When the wafer 10 is exported, the first supporting part 600 may return to the original position.

Although a plurality of the wafers 10 are received, the first and second wafer contacting portions 622 and 642 may be connected to the first and second elastic ribs 630 and 650 respectively so that the wafers 10 may be firmly supported or held.

According to example embodiments, a wafer holding apparatus may include a first supporting part including a first inclined surface and a second inclined surface so that a wafer may be firmly held in the wafer holding apparatus.

In addition, the first supporting part may include elastic material and an elastic ribs so that the wafer may be firmly held due to elastic deformation of the elastic ribs when the wafer is received in the wafer holding apparatus.

In addition, the first inclined surface and the second inclined surface forms an angle so that the wafer may be firmly held in the wafer holding apparatus.

In addition, a first supporting part holder is disposed on an inner wall of a door, so that the first supporting part may be easily coupled to and separated from the door. Thus, the first supporting part may be displaced in due season.

The foregoing is illustrative of example embodiments and is not to be construed as limiting thereof. Although a few example embodiments have been described, those skilled in the art will readily appreciate that many modifications are possible without materially departing from the novel teachings and advantages of the present example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A wafer holding apparatus comprising:
a container body including a space and a front opening, the space configured to receive a wafer;
a door at the front opening; and
a first supporting part on an inner wall of the door, the first supporting part including,
a frame mounted on the inner wall of the door,
a plurality of elastic ribs protruding from the frame and
a support structure coupled to the plurality of elastic ribs and defining a plurality of grooves, the plurality of grooves spaced apart from the door by the elastic ribs and configured to receive a peripheral portion of the wafer.

2. The wafer holding apparatus of claim 1, wherein the first supporting part includes a plurality of wafer contacting portions, and each of the wafer contacting portions includes a first inclined surface and a second inclined surface, the first and second inclined surfaces defining each of the grooves.

3. The wafer holding apparatus of claim 2, wherein the wafer contacting portions are arranged in a direction substantially perpendicular to the wafer, and adjacent wafer contacting portions are configured to be coupled to each other.

4. The wafer holding apparatus of claim 2, wherein the container body includes a top portion, a bottom portion opposite to the top portion, a side portion and a rear portion, the side portion and the rear portion connect the top portion to the bottom portion, second supporting parts are disposed on an inner surface of the side portion, and the first and second supporting parts are configured to support the wafer.

5. The wafer holding apparatus of claim 4, wherein the second supporting part includes a plurality of slits, the slits configured to receive the wafer in an inserted manner.

6. The wafer holding apparatus of claim 4, wherein each of the second supporting parts are disposed on the inner surface of the side portion and an inner surface of the rear portion, and the second supporting part has a shape substantially same as that of the first supporting part.

7. The wafer holding apparatus of claim 6, wherein second supporting part holders on the inner surface of the side portion and the inner surface of the rear portion are configured to hold the second supporting parts, and the second supporting parts are configured to be removable from the second supporting part holders.

8. The wafer holding apparatus of claim 2, wherein a thickness of the elastic ribs of the first supporting part is smaller than that of the frame.

9. The wafer holding apparatus of claim 2, wherein a peak is at a junction at which the second inclined surface and a first inclined surface of an adjacent wafer contacting portion meet, and a protrusion protrudes from the peak in a direction substantially parallel with the wafer.

10. The wafer holding apparatus of claim 2, wherein an angle defined by the first inclined surface and the second inclined surface is about 140 degrees to about 160 degrees.

11. The wafer holding apparatus of claim 2, wherein the wafer contacting portions of the first supporting part includes,
a plurality of first contacting portions and a plurality of second contacting portions spaced apart from the first contacting portions,
each of the first and second contacting portions has the first inclined surface and the second inclined surfaces, the first and second inclined surfaces defining each of the grooves configured to receive the wafer, and
the elastic ribs including first elastic ribs and a second elastic ribs, the first elastic ribs connecting the first wafer contacting portions to the frame and the second elastic ribs connecting the second wafer contacting portions to the frame.

12. The wafer holding apparatus of claim 11, wherein the first wafer contacting portions are arranged in a direction substantially perpendicular to the wafer, the first and second inclined surfaces in each of the first wafer contacting portions arranged continuously and alternately, and
the second wafer contacting portions are arranged in the direction substantially perpendicular to the wafer, the first and second inclined surfaces in each of the second wafer contacting portions arranged continuously and alternately.

13. The wafer holding apparatus of claim 12, wherein an angle defined by the first inclined surface and the second inclined surface is about 140 degrees to 160 degrees.

14. The wafer holding apparatus of claim 1, wherein a first supporting part holder is on the inner wall of the door, and the frame of the first supporting part is coupled to the first supporting part holder.

15. The wafer holding apparatus of claim 1, wherein the first supporting part includes thermo-hardening resin.

16. A wafer holding apparatus comprising:
a container having an open side configured to receive a wafer therethrough;
a door configured to close the open side, and
a supporting part coupled to the door and including at least one groove configured to hold a peripheral portion of the wafer.

17. The wafer holding apparatus of claim 16, wherein the supporting part includes a corrugated support structure defining the at least one groove.

18. The wafer holding apparatus of claim 17, wherein the supporting part is spaced apart from the door by a plurality of elastic ribs connected to the corrugated support structure.

19. The wafer holding apparatus of claim 16, wherein the door includes a holder configured to couple the supporting part with the door.

20. The wafer holding apparatus of claim 19, further comprising:
a plurality of protrusions at a plurality of peaks of the corrugated support structure, the protrusions extending in a direction substantially parallel with the wafer.
